(19) United States
(12) Patent Application Publication
(10) Pub. No.: US 2018/0226559 A1
(43) Pub. Date: Aug. 9, 2018

(54) THERMOELECTRIC CONVERSION DEVICE

(71) Applicant: TDK CORPORATION, Tokyo (JP)

(72) Inventors: Makoto SHIBATA, Tokyo (JP); Kazuya MAEKAWA, Tokyo (JP)

(73) Assignee: TDK CORPORATION, Tokyo (JP)

(21) Appl. No.: 15/882,276

(22) Filed: Jan. 29, 2018

(30) Foreign Application Priority Data
Feb. 3, 2017 (JP) 2017-018971

(51) Int. Cl. H01L 35/32; H01L 35/04; H01L 35/30

(52) U.S. Cl. CPC H01L 35/32; H01L 35/30; H01L 35/04

(57) ABSTRACT

A thermoelectric conversion device includes a first wiring and a second wiring that are arranged between one thermoelectric conversion element array and the other thermoelectric conversion element array adjacent to each other in a second direction, and electrically connect any two of first electrodes and second electrodes of each thermoelectric conversion element so that the thermoelectric conversion elements constituting one thermoelectric conversion element array and the thermoelectric conversion elements constituting the other thermoelectric conversion element array are alternately connected in series, and the first wiring and the second wiring are arranged so that the wirings at least partially intersect each other via an insulating layer as viewed in the thickness direction of the substrate.

### BACKGROUND OF THE INVENTION

### Field of the Invention

The present invention relates to a thermoelectric conversion device. Priority is claimed on Japanese Patent Application No. 2017-018971, filed Feb. 3, 2017, the content of which is incorporated herein by reference.

### Description of Related Art

For example, exhaust heat from an internal combustion engine, a combustion device, or the like dissipates without being used. Therefore, from the viewpoint of energy saving, the use of this exhaust heat has attracted attention in recent years. In particular, research on thermoelectric conversion devices that enable conversion from heat to electricity is being actively conducted (see, for example, WO2011/065185).

Specifically, WO2011/065185 discloses a thermoelectric conversion module (thermoelectric conversion device) including an insulating substrate, multiple thermoelectric conversion material films arranged at intervals on the first surface of the insulating substrate, the first electrode and the second electrode formed apart from each other on the respective thermoelectric conversion material films, the first heat transfer part arranged on the first surface side of the insulating substrate and in which a protrusion that is brought into contact with the first electrode is provided, and the second heat transfer part arranged on the second surface side of the insulating substrate and in which a protrusion that is brought into contact with an area on the second surface side of the insulating substrate and corresponding to the second electrode is provided.

Further, in this thermoelectric conversion module, the first electrode is formed along one side of the thermoelectric conversion material film, and the second electrode is formed along the other side facing one side of the thermoelectric conversion material film

In addition, the first electrode is connected to the second electrode on the thermoelectric conversion material film adjacent to one side, and the second electrode is connected to the first electrode on the thermoelectric conversion material film adjacent to the other side in the thermoelectric conversion module.

### SUMMARY OF THE INVENTION

Meanwhile, in the thermoelectric conversion module described in WO2011/065185 described above, the first electrode and the second electrode of the adjacent thermoelectric conversion material film are connected by a wiring drawn in an outer periphery of the thermoelectric conversion material film. However, in such a configuration, there is a problem in that a sufficient output is not obtained because a routing distance of the wiring becomes longer and resistance of the wiring becomes higher.

The present invention has been proposed in view of such circumstances of the related art, and an object thereof is to provide a thermoelectric conversion device capable of improving an output.

In order to achieve the above object, the present invention provides the following aspects.

A thermoelectric conversion device including:

a substrate including a first surface and a second surface facing each other in a thickness direction;

a pair of thermoelectric conversion element arrays including a plurality of thermoelectric conversion elements aligned in a first direction among the first direction and a second direction intersecting each other in a surface on the first surface side of the substrate, the plurality of thermoelectric conversion elements being arranged side by side in the second direction;

a first electrode electrically connected to one end in the first direction of each of the thermoelectric conversion elements constituting the thermoelectric conversion element array and a second electrode electrically connected to the other end in the first direction of each of the thermoelectric conversion elements; and

a first wiring and a second wiring that are arranged between one thermoelectric conversion element array and the other thermoelectric conversion element array adjacent to each other in the second direction, and electrically connect any two of a plurality of the first electrodes and a plurality of the second electrodes of each thermoelectric conversion element so that the thermoelectric conversion elements constituting the one thermoelectric conversion element array and the thermoelectric conversion elements constituting the other thermoelectric conversion element array are alternately connected in series,

wherein the first wiring and the second wiring are arranged so that the wirings at least partially intersect each other with an insulating layer therebetween as viewed in the thickness direction of the substrate.

### BRIEF DESCRIPTION OF THE DRAWINGS

FIG. 1 is a plan view illustrating a schematic configuration of a thermoelectric conversion device according to the first embodiment of the present invention.

FIG. 2 is a cross-sectional view of the thermoelectric conversion device taken along a line segment A-A illustrated in FIG. 1.

FIG. 3 is a cross-sectional view of the thermoelectric conversion device in which a box portion B illustrated in FIG. 2 is enlarged.

FIG. 4 is a cross-sectional view of the thermoelectric conversion device taken along a line segment C-C illustrated in FIG. 1.

FIG. 5 is a cross-sectional view of the thermoelectric conversion device taken along a line segment D-D illustrated in FIG. 1.

FIG. 6 is a cross-sectional view of the thermoelectric conversion device taken along a line segment E-E illustrated in FIG. 1.

FIG. 7 is a view sequentially illustrating a process of manufacturing the thermoelectric conversion device illustrated in FIG. 1, and is a plan view illustrating a state in which a thermoelectric conversion film is arranged.

FIG. 8 is a view sequentially illustrating a process of manufacturing the thermoelectric conversion device illustrated in FIG. 1, and is a plan view illustrating a state in which the first conductive film constituting the first electrode, the second electrode, the first wiring, and the third wiring is arranged.

FIG. 9 is a view sequentially illustrating a process of manufacturing the thermoelectric conversion device illustrated in FIG. 1, and is a plan view illustrating a state in which an insulating film is arranged.

FIG. 10 is an enlarged plan view of a box portion F illustrated in FIG. 9.

FIG. 11 is a view sequentially illustrating a process of manufacturing the thermoelectric conversion device illustrated in FIG. 1, and is a plan view illustrating a state in which the second conductive film constituting the first electrode, the second electrode, the second wiring, and the third wiring is arranged.

FIG. 12 is a plan view illustrating a schematic configuration of a thermoelectric conversion device according to the second embodiment of the present invention.

FIG. 13A is a plan view illustrating an arrangement of a plurality of thermoelectric conversion devices constituting a pair of thermoelectric conversion element arrays.

FIG. 13B is a plan view illustrating an arrangement of a plurality of thermoelectric conversion devices constituting a pair of thermoelectric conversion element arrays.

FIG. 13C is a plan view illustrating an arrangement of a plurality of thermoelectric conversion devices constituting a pair of thermoelectric conversion element arrays.

FIG. 14A is a cross-sectional view illustrating a modification example of the second heat transfer plate.

FIG. 14B is a cross-sectional view illustrating a modification example of the second heat transfer plate.

### DETAILED DESCRIPTION OF THE INVENTION

Hereinafter, embodiments of the present invention will be described in detail with reference to the drawings.

In the drawings used in the following description, for the sake of easy understanding of the features, characteristic portions may be shown in an enlarged state for convenience, and dimensional ratios of the components are not always the same as actual ratios. Further, materials and the like exemplified in the following description are merely examples, and the present invention is not necessarily limited thereto and can be appropriately changed and carried out within a range defined by the scope of the present invention.

### First Embodiment

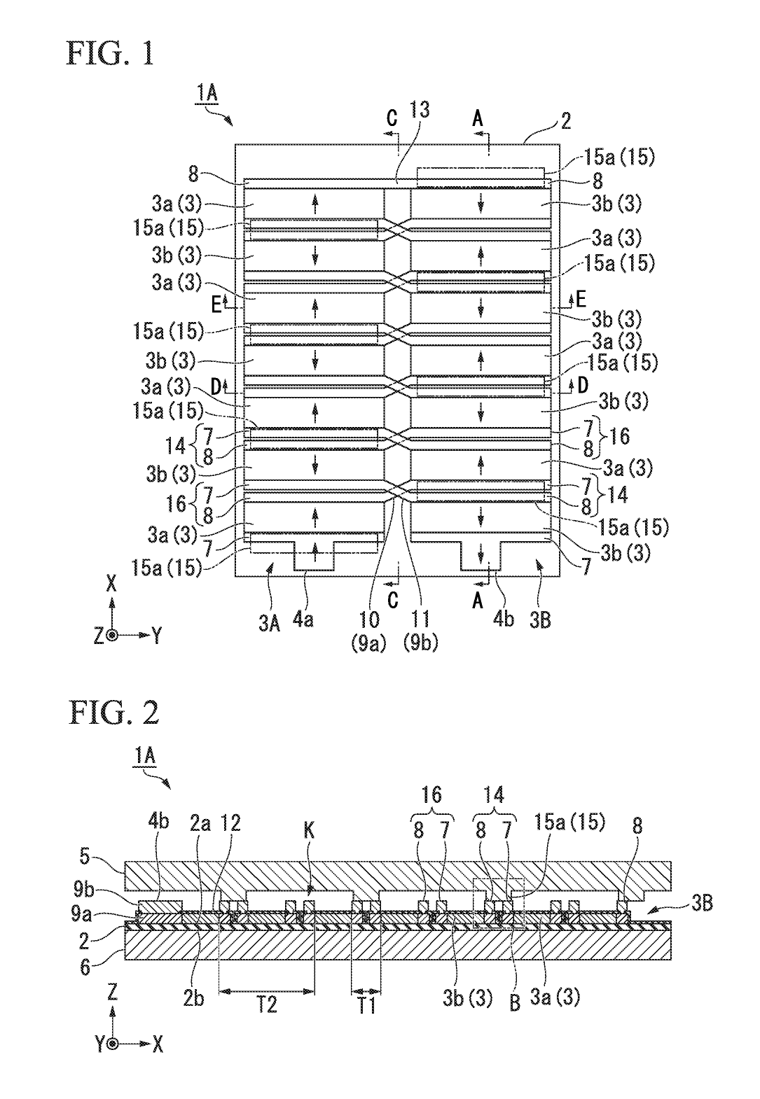

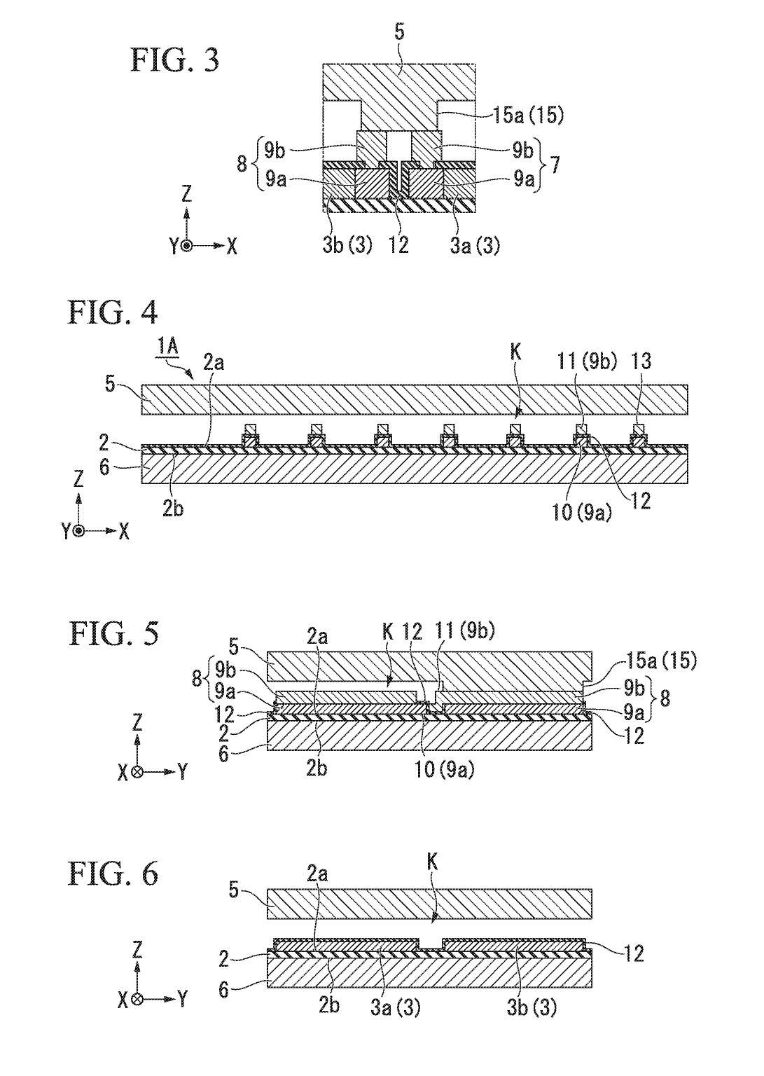

First, for example, a thermoelectric conversion device 1A illustrated in FIGS. 1 to 6 as the first embodiment of the present invention will be described. FIG. 1 is a plan view illustrating a schematic configuration of the thermoelectric conversion device 1A. FIG. 2 is a cross-sectional view of the thermoelectric conversion device 1A taken along a line segment A-A illustrated in FIG. 1. FIG. 3 is a cross-sectional view of the thermoelectric conversion device 1A in which a box portion B illustrated in FIG. 2 is enlarged. FIG. 4 is a cross-sectional view of the thermoelectric conversion device 1A taken along a line segment C-C illustrated in FIG. 1. FIG. 5 is a cross-sectional view of the thermoelectric conversion device 1A taken along a line segment D-D illustrated in FIG. 1. FIG. 6 is a cross-sectional view of the thermoelectric conversion device 1A taken along a line segment E-E illustrated in FIG. 1.

Further, in the following drawings, an XYZ orthogonal coordinate system is set, the X-axis direction is defined as the first direction in the horizontal plane of the thermoelectric conversion device 1A, the Y-axis direction is set as the second direction in the horizontal plane of the thermoelectric conversion device 1, and the Z-axis direction is defined as a thickness direction of the thermoelectric conversion device 1A.

As illustrated in FIGS. 1 to 6, the thermoelectric conversion device 1A of the embodiment has a structure in which multiple thermoelectric conversion elements 3 arranged side by side on a surface of a substrate 2 are connected in series between a pair of terminals 4a and 4b. Further, in the thermoelectric conversion device 1A, the substrate 2 on which multiple thermoelectric conversion elements 3 are arranged is sandwiched between the first heat transfer plate 5 that is a high temperature (heating) side and the second heat transfer plate 6 that is a low temperature (heat radiation/cooling) side.

The substrate 2 is formed of an insulating base material including the first surface (an upper surface in the embodiment) 2a and the second surface (a lower surface in the embodiment) 2b that face each other in the thickness direction. It is preferable for, for example, a high resistance silicon (Si) substrate having a substrate resistance of 10 Ω or more to be used as the substrate 2.

By setting the substrate resistance to 10 Ω or more, it is possible to prevent an electrical short-circuit from occurring between multiple thermoelectric conversion elements 3.

Further, in addition to the high resistance Si substrate described above, for example, a silicon on insulator (SOI) substrate having an oxide insulating layer in the substrate, a ceramic substrate, a high-resistance single crystal substrate, or the like can be used as the substrate 2. Further, a low resistance substrate having substrate resistance of 10 Ω or less in which a high resistance material is arranged between the low resistance substrate and the thermoelectric conversion element 3 can be used as the substrate 2.

The thermoelectric conversion element 3 is formed of a thermoelectric conversion film which is any one of a p-type semiconductor and an n-type semiconductor (a p-type semiconductor in the embodiment). When the thermoelectric conversion element 3 is a p-type thermoelectric conversion film, for example, a multilayer film including a p-type silicon (Si) film doped with boron (B) at a high concentration (10¹⁸ to 10¹⁹ cm³) and a p-type silicon-germanium (SiGe) alloy film can be used. Further, multiple thermoelectric conversion elements 3 may be p-type semiconductors having the same configuration or may be p-type semiconductors having different configurations. When the thermoelectric conversion element 3 is the p-type semiconductor, current flows from a hot junction side to a cold junction side in the thermoelectric conversion element 3.

On the other hand, when the thermoelectric conversion element 3 is an n-type thermoelectric conversion film, for example, a multilayer film of an n-type silicon (Si) film doped with antimony (Sb) at a high concentration (10¹⁸ to 10¹⁹ cm³) and an n-type silicon-germanium (SiGe) alloy film can be used. Further, multiple thermoelectric conversion elements 3 may be n-type semiconductors having the same configuration or may be n-type semiconductors having different configurations. When the thermoelectric conversion element 3 is the n-type semiconductor, current flows from a cold junction side to a hot junction side in the thermoelectric conversion element 3.

Further, the thermoelectric conversion element 3 is not necessarily limited to the multilayer film of a p-type or n-type semiconductor described above, and may be a single layer film of a p-type or n-type semiconductor. Further, an oxide semiconductor can also be used as the semiconductor. Further, for example, a thermoelectric conversion film formed of an organic polymer film, a metal film, or the like can be used. Further, the thermoelectric conversion element 3 is not limited to the above-described thermoelectric conversion film, and a thermoelectric conversion film element formed of bulk may be used.

The thermoelectric conversion device 1A of the embodiment includes multiple (seven in the embodiment) thermoelectric conversion elements 3 that are aligned in the first direction among the first direction and the second direction intersecting each other (orthogonal to each other in the embodiment) in a surface of the first surface 2a of the substrate 2. Further, the thermoelectric conversion device 1A includes a pair (two columns) of thermoelectric conversion element arrays 3A and 3B in which the multiple thermoelectric conversion elements 3 are arranged side by side in the second direction.

The thermoelectric conversion elements 3 constituting the thermoelectric conversion element arrays 3A and 3B are formed with the same size in an oblong shape (a rectangular shape in the embodiment) in a plan view. Further, the respective thermoelectric conversion elements 3 are arranged side by side at regular intervals in the first direction with the first direction as a lateral direction and the second direction as a longitudinal direction. Further, the one thermoelectric conversion element array 3A and the other thermoelectric conversion element array 3B adjacent to each other in the second direction are arranged in parallel at regular intervals.

Each of the thermoelectric conversion elements 3 constituting the thermoelectric conversion element arrays 3A and 3B includes the first electrode 7 electrically connected to one end (−X axis) in the first direction and the second electrode 8 electrically connected to the other end (+X axis) in the first direction.

Each of the first electrode 7 and the second electrode 8 is formed of a laminated film in which the first conductive film 9a and the second conductive film 9b are sequentially laminated. It is preferable for a metal to be used as a material of the first conductive film 9a and the second conductive film 9b. In particular, a metal with high electrical conductivity and thermal conductivity and easy shape processing, such as copper (Cu) or gold (Au), can be suitably used. As the materials of the first conductive film 9a and the second conductive film 9b, the same metal may be used or different metals may be used.

Among the first conductive film 9a and the second conductive film 9b constituting the first electrode 7 and the second electrode 8, the first conductive film 9a is formed with substantially the same thickness as the thermoelectric conversion element 3. On the other hand, the second conductive film 9b is formed to overlap the first conductive film 9a in a plan view on the first conductive film 9a. Therefore, the first electrode 7 and the second electrode 8 are provided to protrude upward (+Z-axis direction) by a thickness of the second conductive film 9b as compared with the thermoelectric conversion element 3 in the thickness direction.

The first electrode 7 and the second electrode 8 are formed with the same size in an oblong shape (a rectangular shape in the embodiment) in a plan view over the entire region in the longitudinal direction (second direction) of the thermoelectric conversion element 3 in a state in which the first electrode 7 and the second electrode 8 are brought into contact with a side surface on one end side and a side surface on the other end side facing each other in the first direction of the thermoelectric conversion element 3, respectively. Further, the first electrode 7 (or the second electrode 8) of one thermoelectric conversion element 3 and the second electrode 8 (or the first electrode 7) of the other thermoelectric conversion element 3 are arranged apart from each other between the first thermoelectric conversion element 3 and the other thermoelectric conversion element 3 adjacent to each other in the first direction.

The pair of thermoelectric conversion element arrays 3A and 3B have a configuration in which the thermoelectric conversion element 3 in which current flows from the first electrode 7 to the second electrode 8 (hereinafter referred to as a “thermoelectric conversion element 3a” as necessary) and the thermoelectric conversion element 3 in which current flows from the second electrode 8 to the first electrode 7 (hereinafter referred to as a “second thermoelectric conversion element 3b” as necessary) among multiple thermoelectric conversion elements 3 are arranged side by side alternately in the first direction.

In FIG. 1, a direction (+X-axis direction) of a current flowing through one terminal 4a and the first thermoelectric conversion element 3a and a direction (−X-axis direction) of a current flowing to the other terminal 4b and the second thermoelectric conversion element 3b are indicated by arrow directions.

Further, the pair of thermoelectric conversion element arrays 3A and 3B have a configuration in which the thermoelectric conversion elements 3 in which directions of the currents flowing between the first electrode 7 and the second electrode 8 are opposite to each other among multiple thermoelectric conversion elements 3 are arranged side by side in the second direction. That is, the first thermoelectric conversion element 3a (or the second thermoelectric conversion element 3b ) and the second thermoelectric conversion element 3b (or the first thermoelectric conversion element 3a) are arranged side by side in the second direction between the first thermoelectric conversion element array 3A and the other thermoelectric conversion element array 3B.

The pair of terminals 4a and 4b are made of a laminated film in which the first conductive film 9a and the second conductive film 9b are sequentially laminated, similar to the first electrode 7 and the second electrode 8 described above. Among them, the one terminal 4a is electrically connected to the first electrode 7 of the thermoelectric conversion element 3 (the first thermoelectric conversion element 3a) located on one endmost (−X axis) side in the first direction among the thermoelectric conversion elements 3 constituting one thermoelectric conversion element array 3A. That is, the one terminal 4a is formed of a laminated film of the first conductive film 9a and the second conductive film 9b continuous with the first electrode 7 to protrude in an oblong shape (a rectangular shape in the embodiment) in a plan view toward the outside (on the −X axis side) of the first electrode 7.

On the other hand, the other terminal 4b is electrically connected to the first electrode 7 of the thermoelectric conversion element 3 (the second thermoelectric conversion element 3b ) located on the one endmost (−X axis) side in the first direction among the thermoelectric conversion elements 3 constituting the other thermoelectric conversion element array 3B. That is, the other terminal 4b is formed of a laminated film of the first conductive film 9a and the second conductive film 9b continuous with the first electrode 7 to protrude in an oblong shape (a rectangular shape in the embodiment) in a plan view toward the outside (on the −X axis side) of the first electrode 7.

The first wiring 10 and the second wiring 11 that electrically connect any two of the first electrodes 7 and the second electrodes 8 of each thermoelectric conversion element 3 are arranged between the one thermoelectric conversion element array 3A and the other thermoelectric conversion element array 3B.

Among them, the first wiring 10 is linearly formed of the first conductive film 9a continuous with the first conductive film 9a of a lower layer constituting the first electrode 7 and the second electrode 8 described above. On the other hand, the second wiring 11 is linearly formed of the second conductive film 9b continuous with the second conductive film 9b of an upper layer constituting the first electrode 7 and the second electrode 8 described above.

The first wiring 10 and the second wiring 11 electrically connect any two of the first electrodes 7 and the second electrodes 8 of each thermoelectric conversion element 3 so that the thermoelectric conversion elements 3 constituting one thermoelectric conversion element array 3A and the thermoelectric conversion elements 3 constituting the other thermoelectric conversion element array 3B are alternately connected in series between the one terminal 4a and the other terminal 4b.

Specifically, the second electrode 8 of the thermoelectric conversion element 3 located at an n-th position (n is a natural number) from the one end (−X axis) in the first direction among the thermoelectric conversion elements 3 constituting the one thermoelectric conversion element array 3A, and the first electrode 7 of the thermoelectric conversion element 3 located at an (n+1)-th position from the one end (−X axis) in the first direction among the thermoelectric conversion elements 3 constituting the other thermoelectric conversion element array 3B are electrically connected via the first wiring 10 (the first conductive film 9a) arranged obliquely with respect to the second direction. (Here, n=1 to 6 in the embodiment.)

Further, the second electrode 8 of the thermoelectric conversion element 3 located at an n-th position from the one end (−X axis) in the first direction among the thermoelectric conversion elements 3 constituting the other thermoelectric conversion element array 3B, and the first electrode 7 of the thermoelectric conversion element 3 located at an (n+1)-th position from the one end (−X axis) in the first direction among the thermoelectric conversion elements 3 constituting the other thermoelectric conversion element array 3A are electrically connected via the second wiring 11 (second conductive film 9b) arranged obliquely in a direction opposite to the first wiring 10 with respect to the second direction. (Here, n=1 to 6 in the embodiment.)

Further, the second electrode 8 of the thermoelectric conversion element 3 located on the other endmost (+X axis) side in the first direction among the thermoelectric conversion elements 3 constituting the one thermoelectric conversion element array 3A, and the second electrode 8 of the thermoelectric conversion element 3 located on the other endmost (+X axis) side in the first direction among the thermoelectric conversion elements 3 constituting the other thermoelectric conversion element array 3B are electrically connected via the third wiring 13 arranged in parallel to the second direction. The third wiring 13 is formed of a laminated film in which the first conductive film 9a and the second conductive film 9b are sequentially laminated, similar to the first electrode 7 and second electrode 8 described above.

Thus, the thermoelectric conversion device 1A of the embodiment has a configuration in which the first thermoelectric conversion element 3a constituting the one thermoelectric conversion element array 3A and the first thermoelectric conversion element 3a constituting the other thermoelectric conversion element array 3B are alternately connected in series from the one terminal 4a to the other end (+X axis) in the first direction, and then the second thermoelectric conversion element 3b constituting the one thermoelectric conversion element array 3A and the second thermoelectric conversion element 3b constituting the other thermoelectric conversion element array 3B are alternately connected in series from the other end (+X axis) in the first direction to the other terminal 4b.

The first wiring 10 (the first conductive film 9a) and the second wiring 11 (the second conductive film 9b) are arranged at a height position at which they do not overlap each other in the thickness direction with the insulating film 12 arranged therebetween. That is, the first wiring 10 and the second wiring 11 are electrically insulated from each other via the insulating film 12. Accordingly, the first wiring 10 and the second wiring 11 are arranged such that the wirings 10 and 11 at least partially intersect each other with the insulating film 12 therebetween as viewed in the thickness direction of the substrate 2.

The insulating film 12 may be a material (insulating layer) that can electrically insulate the first wiring 10 (the first conductive film 9a) and the second wiring 11 (the second conductive film 9b). For example, silicon oxide (SiO2), silicon nitride (SiN), or the like can be used. The insulating film 12 is formed to a predetermined thickness over the entire surface between the first wiring 10 (the first conductive film 9a) and the second wiring 11 (the second conductive film 9b) other than a position at which the first electrode 7 and the second electrode 8 are formed.

The first heat transfer plate 5 is arranged on the first surface 2a side of the substrate 2 as the first heat transfer part on the high temperature (heating) side. The first heat transfer plate 5 is formed of a material having a thermal conductivity higher than that of air, and preferably a material having a thermal conductivity higher than that of the substrate 2. It is preferable for a metal to be used as such a material of the first heat transfer plate 5. In particular, a metal with high electrical conductivity and thermal conductivity and easy shape processing, such as aluminum (Al) or copper (Cu), can be suitably used. Further, the first heat transfer plate 5 may be formed of multiple heat transfer parts.

The first heat transfer plate 5 is thermally bonded to the first electrode 7 and the second electrode 8 which are on the hot junction side (hereinafter collectively referred to as a “hot junction side electrode 14”) via the heat transfer portion 15. The hot junction side electrode 14 is formed of the first electrode 7 of the first thermoelectric conversion element 3a and the second electrode 8 of the second thermoelectric conversion element 3b which are adjacent in the first direction. Therefore, the hot junction side electrodes 14 are alternately arranged side by side in the first direction between the one thermoelectric conversion element array 3A and the other thermoelectric conversion element array 3B.

On the other hand, the first electrode 7 and the second electrode 8 which are on the cold junction side (hereinafter collectively referred to as a “cold junction side electrode 16”) are made of the second electrode 8 of the first thermoelectric conversion elements 3a and the first electrode 7 of the second thermoelectric conversion element 3b which are adjacent in the first direction. Therefore, the cold junction side electrodes 16 are alternately arranged side by side in the first direction between the one thermoelectric conversion element array 3A and the other thermoelectric conversion element array 3B.

That is, the hot junction side electrode 14 (or the cold junction side electrode 16) and the cold junction side electrode 16 (or the hot junction side electrode 14) are arranged side by side in the second direction between the one thermoelectric conversion element array 3A and the other thermoelectric conversion element array 3B.

The heat transfer portion 15 has a protrusion 15a protruding from one of the mutually facing surfaces of the first heat transfer plate 5 and the hot junction side electrode 14. The heat transfer portion 15 of the embodiment includes multiple protrusions 15a protruding downward (in the −Z axis direction) from a position facing each hot junction side electrode 14 of the first heat transfer plate 5. Each of the protrusions 15a has an oblong shape in a plan view (a rectangular shape in a cross section in the embodiment) and is provided to protrude in a range in which the protrusion overlaps the first electrode 7 and the second electrode 8 constituting each hot junction side electrode 14. Further, a tip of each protrusion 15a is thermally bonded to each hot junction side electrode 14 in a state in which the tip is electrically insulated from the hot junction side electrode 14 via, for example, an insulating bonding material (not illustrated). The bonding material is formed of an insulating material having a thermal conductivity higher than that of air. As such a material of the bonding material, for example, a UV curing type resin, a silicone type resin, a thermal conductive grease (for example, a silicone type grease or a non-silicone type grease containing a metal oxide), or the like can be used.

When the heat transfer portion 15 is electrically insulated from the hot junction side electrode 14 by an insulating layer or the like provided at the tip of the above described protrusion 15a; or when the presence or the absence of the electrical insulation between the tip of the protrusion 15a and the hot junction side electrode 14 does not matter, the heat transfer portion 15 may be directly bonded to the hot junction side electrode 14 without using the above-described insulating bonding material.

Further, the heat transfer portion 15 does not necessarily include the protrusion 15a protruding from the first heat transfer plate 5 described above, but can also include a protrusion protruding from the hot junction side electrode 14. Further, as the heat transfer portion 15, another heat transfer part (including the bonding material) for thermally bonding the first heat transfer plate 5 and the hot junction side electrode 14 can also be provided. For example, by setting the thickness of the hot junction side electrode 14 to be larger than the thickness of the cold junction side electrode 16, the first heat transfer plate 5 and the hot junction side electrode 14 can be thermally bonded to each other via the bonding material as the heat transfer portion 15 without the protrusion 15a described above.

Further, the first heat transfer plate 5 and the hot junction side electrode 14 are not necessarily thermally bonded via the heat transfer portion 15 described above, but it is also possible to adopt a configuration in which the first heat transfer plate 5 and the hot junction side electrode 14 are directly joined without the insulating bonding material described above when the first heat transfer plate 5 and the hot junction side electrode 14 are electrically insulated from each other, for example, by an insulating layer provided on the surface of the first heat transfer plate 5; or when the presence or the absence of the electrical insulation between the first heat transfer plate 5 and the hot junction side electrode 14 does not matter.

Further, in the thermoelectric conversion device 1A, a space K is provided between the first surface 2a of the substrate 2 and the first heat transfer plate 5 by bonding the first heat transfer plate 5 and the hot junction side electrode 14 described above via the heat transfer portion 15 (protrusion 15a). In the thermoelectric conversion device 1A, it is also possible to fill this space K with a heat insulating material formed of a material having a thermal conductivity lower than that of the heat transfer portion 15. That is, the heat transfer portion 15 forms a portion having a relatively higher thermal conductivity than its surroundings (the space K or the heat insulating material) between the first heat transfer plate 5 and the hot junction side electrode 14.

The second heat transfer plate 6 is arranged on the second surface 2b of the substrate 2 as the second heat transfer part on the low temperature (heat radiation/cooling) side. The second heat transfer plate 6 is formed of a material having a thermal conductivity higher than that of air, and preferably a material having a thermal conductivity higher than that of the substrate 2. As such a material of the second heat transfer plate 6, the same material as that exemplified in the first heat transfer plate 5 described above can be used. Further, the second heat transfer plate 6 may include multiple heat transfer parts.

The second heat transfer plate 6 is thermally bonded to the second surface 2b of the substrate 2 in at least a range T1 in which the second heat transfer plate 6 overlaps at least the heat transfer portion 15 (the protrusion 15a) in the thickness direction. Further, it is preferable for the second heat transfer plate 6 to be thermally bonded to the second surface 2b of the substrate 2 in a range T2 in which the second heat transfer plate 6 overlaps a region from the cold junction side electrode 16 to the heat transfer portion 15 (the protrusion 15a) in the thickness direction. The second heat transfer plate 6 of the embodiment is thermally bonded to the entire surface of the second surface 2b of the substrate 2.

The second heat transfer plate 6 can also have a shape suitable for heat radiation or cooling. For example, in order to cool the second heat transfer plate 6 with air, a heat radiation fin (heat sink) may be provided on the surface of the second heat transfer plate 6 on the side opposite to the substrate 2. In order to cool the second heat transfer plate 6 with water, a flow path for allowing coolant to flow inside the second heat transfer plate 6 may be provided.

In the thermoelectric conversion device 1A having the above configuration, the first heat transfer plate 5 is arranged on the high temperature (heating) side and the second heat transfer plate 6 is arranged on the low temperature (heat radiation/cooling) side. Accordingly, a temperature of the hot junction side electrode 14 side of each thermoelectric conversion element 3 becomes relatively higher due to the heat transferred from the first heat transfer plate 5 to the hot junction side electrode 14 via the heat transfer portion 15. On the other hand, since heat transferred to each thermoelectric conversion element 3 is radiated from the cold junction side electrode 16 to the outside via the substrate 2 and the second heat transfer plate 6, a temperature of the cold junction side electrode 16 side of each thermoelectric conversion element 3 becomes relatively lower. Therefore, a temperature difference is generated between the hot junction side electrode 14 and the cold junction side electrode 16 of each thermoelectric conversion element 3.

Accordingly, movement of charge (carriers) is caused between the first electrode 7 and the second electrode 8 of each thermoelectric conversion element 3. That is, an electromotive force (voltage) due to the Seebeck effect is generated between the first electrode 7 and the second electrode 8 of each thermoelectric conversion element 3, and in each thermoelectric conversion element 3, current flows from the hot junction side electrode 14 to the cold junction side electrode 16.

The electromotive force (voltage) generated in one thermoelectric conversion element 3 is small, but multiple thermoelectric conversion elements 3 are connected in series between the one terminal 4a and the other terminal 4b. Therefore, a relatively high voltage can be extracted as a total electromotive force between the one terminal 4a and the other terminal 4b.

Meanwhile, in the thermoelectric conversion device 1A of the embodiment, the first wiring 10 and the second wiring 11 are arranged between the one thermoelectric conversion element arrays 3A and the other thermoelectric conversion element array 3B adjacent to each other as described above, so that the wirings 10 and 11 at least partially intersect with each other via the insulating film 12 as viewed in the thickness direction of the substrate 2.

Accordingly, in the thermoelectric conversion device 1A of the embodiment, it is possible to shorten a routing distance of the first wiring 10 and the second wiring 11 as compared with that in the related art, and decrease resistance of the first wiring 10 and the second wiring 11.

Therefore, in the thermoelectric conversion device 1A of the embodiment, it is possible to suppress a loss when the current generated in each thermoelectric conversion element 3 flows through the first wiring 10 and the second wiring 11, and as a result, to achieve improvement of an output (power).

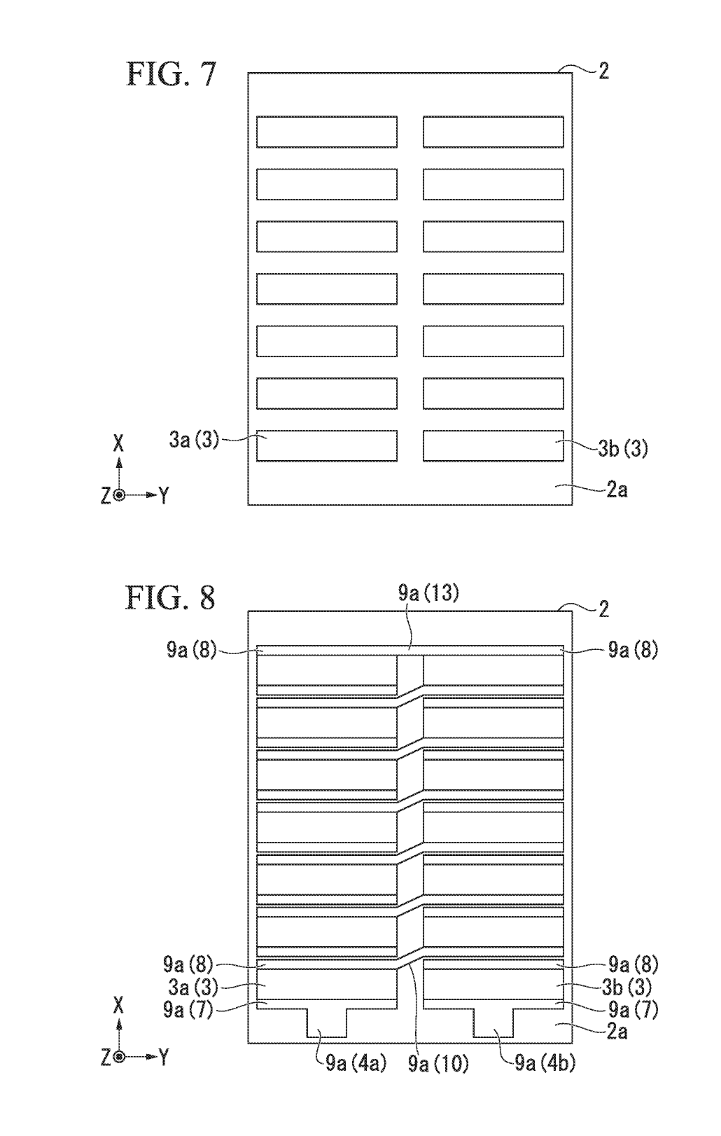

Next, a process of manufacturing the thermoelectric conversion device 1A will be described with reference to FIGS. 7 to 11.

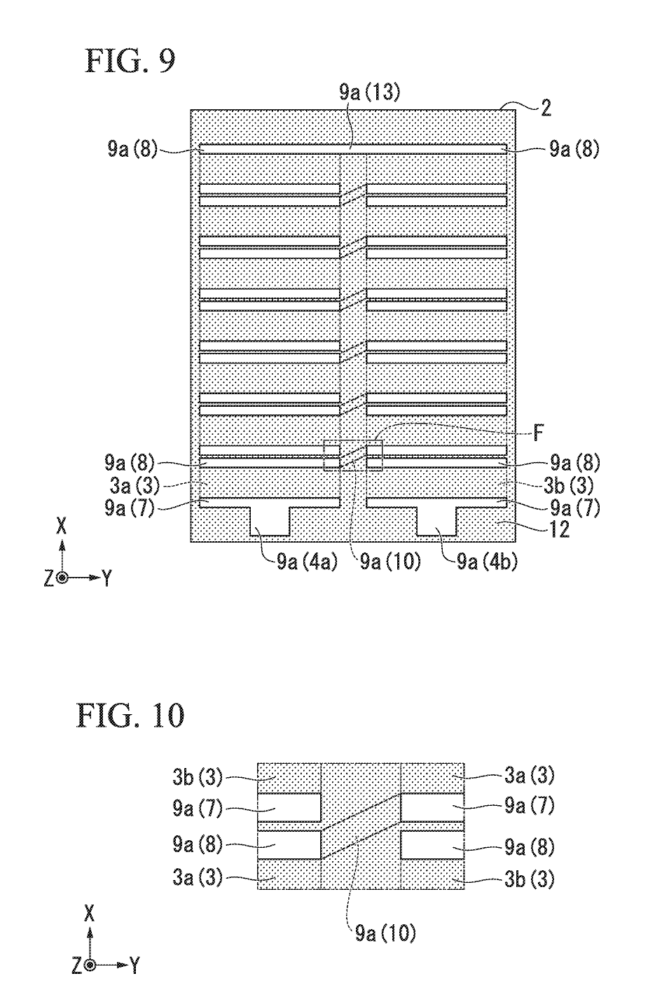

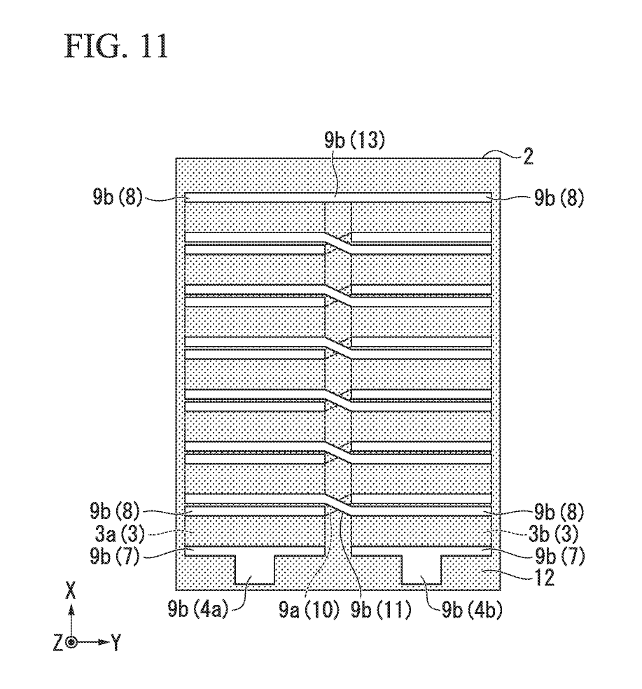

FIG. 7 is a view sequentially illustrating the process of manufacturing the thermoelectric conversion device 1A, and is a plan view illustrating a state in which a thermoelectric conversion film is arranged. FIG. 8 is a view sequentially illustrating the process of manufacturing the thermoelectric conversion device 1A, and is a plan view illustrating a state in which the first conductive film 9a constituting the first electrode 7, the second electrode 8, the first wiring 10, and the third wiring 13 is arranged. FIG. 9 is a view sequentially illustrating the process of manufacturing a thermoelectric conversion device 1A, and is a plan view illustrating a state in which the insulating film 12 is arranged. FIG. 10 is an enlarged plan view of a box portion F illustrated in FIG. 9. FIG. 11 is a view sequentially illustrating the process of manufacturing the thermoelectric conversion device 1A, and is a plan view illustrating a state in which the second conductive film 9b constituting the first electrode 7, the second electrode 8, the second wiring 11, and the third wiring 13 is arranged.

When the thermoelectric conversion device 1A is manufactured, a thermoelectric conversion film is first formed on the first surface 2a of the substrate 2, and then, the thermoelectric conversion film is selectively removed by etching, as illustrated in FIG. 7. Accordingly, multiple thermoelectric conversion elements 3 (a pair of thermoelectric conversion element arrays 3A and 3B) patterned in the above-described shape are formed.

Then, as illustrated in FIG. 8, a mask (not illustrated) having openings at positions corresponding to the first electrode 7 and the second electrode 8 of each thermoelectric conversion element 3, and the first wiring 10 and the third wiring 13 is formed, the first conductive film 9a is formed, and then, the mask is removed. Accordingly, the first conductive film 9a corresponding to the first electrode 7 and the second electrode 8 of each thermoelectric conversion element 3, and the first wiring 10 and the third wiring 13 is formed.

Then, as illustrated in FIGS. 9 and 10, a mask is formed at positions corresponding to the first electrode 7 and the second electrode 8 of each thermoelectric conversion element 3, an insulating film 12 is formed, and then, the mask is removed. Accordingly, the insulating film 12 having openings is formed at positions corresponding to the first electrode 7 and the second electrode 8 of each thermoelectric conversion element 3, and the third wiring 13.

Then, as illustrated in FIG. 11, a mask (not illustrated) having openings at positions corresponding to the first electrode 7 and the second electrode 8 of each thermoelectric conversion element 3, and the second wiring 11 is formed, the second conductive film 9b is formed, and then, the mask is removed. Accordingly, the second conductive film 9b corresponding to the first electrode 7 and the second electrode 8 of each thermoelectric conversion element 3, and the second wiring 11 and the third wiring 13 is formed.

Through the above process, the first wiring 10 and the second wiring 11 can be arranged between the one thermoelectric conversion element arrays 3A and the other thermoelectric conversion element array 3B adjacent to each other as described above, so that the wirings 10 and 11 at least partially intersect with each other via the insulating film 12 as viewed in the thickness direction of the substrate 2.

Then, the substrate 2 obtained in the process illustrated in FIG. 11 is bonded in a state in which the substrate 2 is sandwiched between the first heat transfer plate 5 having the protrusion 15a formed therein, which is the heat transfer portion 15, and the second heat transfer plate 6. Accordingly, the thermoelectric conversion device 1A can be manufactured.

In the thermoelectric conversion device 1A of the embodiment, the first wiring 10 (the first conductive film 9a) on the lower layer side and the second wiring 11 (the second conductive film) on the upper layer side are arranged so that the wirings 10 and 11 at least partially intersect each other via the insulating film 12 as viewed from the thickness direction of the substrate 2 described above. However, the arrangement in the thickness direction of the first wiring 10 and the second wiring 11 can be reversed. That is, the first wiring 10 can be the second conductive film 9b on the upper layer side, and the second wiring 11 can be the first conductive film 9a on the lower layer side.

### Second Embodiment

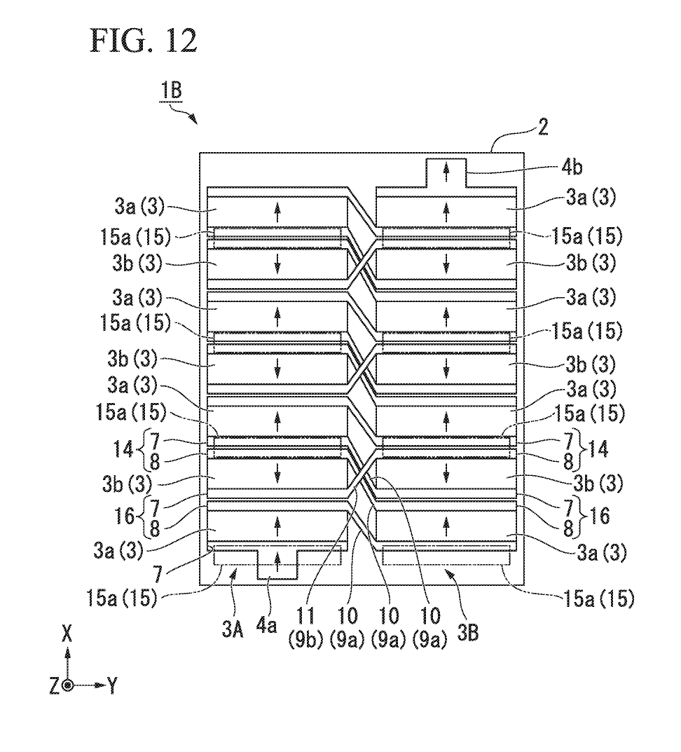

Next, a thermoelectric conversion device 1B illustrated in FIG. 12 as the second embodiment of the present invention, for example, will be described. FIG. 12 is a plan view illustrating a schematic configuration of the thermoelectric conversion device 1B. Further, hereinafter, the same components as those of the above-described thermoelectric conversion device 1A is not be described and are denoted with the same reference numerals in the drawings.

As illustrated in FIG. 12, the thermoelectric conversion device 1B of the embodiment has basically the same configuration as the above-described thermoelectric conversion device 1A except that the arrangement of the first thermoelectric conversion element 3a and the second thermoelectric conversion element 3b is different from that of the thermoelectric conversion device 1A.

In FIG. 12, a direction (+X-axis direction) of a current flowing through one terminal 4a and the first thermoelectric conversion element 3a and a direction (−X-axis direction) of a current flowing through the other terminal 4b and the second thermoelectric conversion element 3b are indicated by arrow directions, respectively.

Specifically, in the thermoelectric conversion device 1B, the thermoelectric conversion elements 3 in which directions of the currents flowing between the first electrode 7 and the second electrode 8 are the same direction among multiple thermoelectric conversion elements 3 constituting the pair of thermoelectric conversion element arrays 3A and 3B are arranged side by side in the second direction. That is, the first thermoelectric conversion elements 3a are aligned in the second direction and the second thermoelectric conversion elements 3b are arranged side by side in the second direction between the one thermoelectric conversion element array 3A and the other thermoelectric conversion element array 3B.

Further, hot junction side electrodes 14 are aligned in the second direction, and cold side electrodes 16 are arranged side by side in the second direction between the one thermoelectric conversion element array 3A and the other thermoelectric conversion element array 3B. A heat transfer portion 15 (a protrusion 15a) is arranged at a position facing each hot junction side electrode 14 in a thickness direction of a substrate 2.

Further, the one terminal 4a is electrically connected to the first electrode 7 of the thermoelectric conversion elements 3 (the first thermoelectric conversion element 3a) located at one endmost (−X axis) side in the first direction among the thermoelectric conversion elements 3 constituting the one thermoelectric conversion element array 3A. On the other hand, the other terminal 4b is electrically connected to the second electrode 8 of the thermoelectric conversion elements 3 (the first thermoelectric conversion element 3a) located at the other endmost (+X axis) side in the first direction among the thermoelectric conversion elements 3 constituting the other thermoelectric conversion element array 3B.

The first wiring 10 and the second wiring 11 electrically connect any two of the first electrodes 7 and the second electrodes 8 of each thermoelectric conversion element 3 so that the thermoelectric conversion elements 3 constituting one thermoelectric conversion element array 3A and the thermoelectric conversion elements 3 constituting the other thermoelectric conversion element array 3B are alternately connected in series between the one terminal 4a and the other terminal 4b.

Specifically, the second electrode 8 of the thermoelectric conversion element 3 located at an (2n−1)-th position (n is a natural number) from the one end (−X axis) in the first direction among the thermoelectric conversion elements 3 constituting the one thermoelectric conversion element array 3A, and the first electrode 7 of the thermoelectric conversion element 3 located at a (2n−1)-th position from the one end (−X axis) in the first direction among the thermoelectric conversion elements 3 constituting the other thermoelectric conversion element array 3B are electrically connected via the first wiring 10 (the first conductive film 9a) arranged obliquely with respect to the second direction. (Here, n=1 to 4 in the embodiment.)

Further, the second electrode 8 of the thermoelectric conversion element 3 located at an 2n-th position from the one end (−X axis) in the first direction among the thermoelectric conversion elements 3 constituting the one thermoelectric conversion element array 3A, and the second electrode 8 of the thermoelectric conversion element 3 located at a (2n−1)-th position from the one end (−X axis) in the first direction among the thermoelectric conversion elements 3 constituting the other thermoelectric conversion element array 3B are electrically connected via the first wiring 10 (the first conductive film 9a) arranged obliquely with respect to the second direction. (Here, n=1 to 3 in the embodiment.)

Further, the first electrode 7 of the thermoelectric conversion element 3 located at a (2n+1)-th position (n is a natural number) from the one end (−X axis) in the first direction among the thermoelectric conversion elements 3 constituting the one thermoelectric conversion element array 3A, and the first electrode 7 of the thermoelectric conversion element 3 located at a 2n-th position from the one end (−X axis) in the first direction among the thermoelectric conversion elements 3 constituting the other thermoelectric conversion element array 3B are electrically connected via the first wiring 10 (the first conductive film 9a) arranged obliquely with respect to the second direction. (Here, n=1 to 3 in the embodiment.)

Further, the first electrode 7 of the thermoelectric conversion element 3 located at a 2n-th position from the one end (−X axis) in the first direction among the thermoelectric conversion elements 3 constituting the one thermoelectric conversion element array 3A, and the second electrode 8 of the thermoelectric conversion element 3 located at a 2n-th position from the one end (−X axis) in the first direction among the thermoelectric conversion elements 3 constituting the other thermoelectric conversion element array 3B are electrically connected via the second wiring 11 (the second conductive film 9b) arranged obliquely in a direction opposite to the first wiring 10 with respect to the second direction. (Here, n=1 to 3 in the embodiment.)

Thus, the thermoelectric conversion device 1B of the embodiment has a configuration in which the first thermoelectric conversion element 3a constituting the one thermoelectric conversion element array 3A and the first thermoelectric conversion element 3a constituting the other thermoelectric conversion element array 3B are connected in series, and then, the second thermoelectric conversion element 3b constituting the one thermoelectric conversion element array 3A and the second thermoelectric conversion element 3b constituting the other thermoelectric conversion element array 3B are connected in series, and multiple thermoelectric conversion elements 3 are connected in series while alternately repeating such a connection from the one terminal 4a to the other end 4b.

The first wiring 10 (the first conductive film 9a) and the second wiring 11 (the second conductive film 9b) are arranged at a height position not to overlap each other in the thickness direction via the insulating film 12 arranged therebetween. That is, the first wiring 10 and the second wiring 11 are electrically insulated from each other via the insulating film 12. Accordingly, the first wiring 10 and the second wiring 11 are arranged such that the wirings 10 and 11 at least partially intersect each other via the insulating film 12 as viewed in the thickness direction of the substrate 2.

Accordingly, in the thermoelectric conversion device 1B of the embodiment, it is possible to shorten a routing distance of the first wiring 10 and the second wiring 11 as compared with that in the related art, and decrease resistance of the first wiring 10 and the second wiring 11.

Therefore, in the thermoelectric conversion device 1B of the embodiment, it is possible to suppress a loss when the current generated in each thermoelectric conversion element 3 flows through the first wiring 10 and the second wiring 11, and as a result, to achieve improvement of an output, as in the thermoelectric conversion device 1A.

In the thermoelectric conversion device 1B of the embodiment, the first wiring 10 (the first conductive film 9a) on the lower layer side and the second wiring 11 (the second conductive film) on the upper layer side are arranged so that the wirings 10 and 11 at least partially intersect each other via the insulating film 12 as viewed from the thickness direction of the substrate 2 described above. However, the arrangement in the thickness direction of the first wiring 10 and the second wiring 11 can be reversed. That is, the first wiring 10 can be the second conductive film 9b on the upper layer side, and the second wiring 11 can be the first conductive film 9a on the lower layer side.

The present invention is not necessarily limited to the above embodiment, and various modifications can be made without departing from the scope of the present invention.

For example, in the above embodiment, each of multiple thermoelectric conversion elements 3 aligned in the first direction have a rectangular shape, and multiple thermoelectric conversion elements 3 are arranged side by side in the second direction orthogonal to the first direction in the surface of the substrate 2. On the other hand, multiple thermoelectric conversion elements 3 are not necessarily required to have the rectangular shape, and the shape, the number, and the like thereof can be appropriately changed. Further, multiple thermoelectric conversion elements 3 are not necessarily limited to the configuration in which multiple thermoelectric conversion elements 3 are arranged in the second direction orthogonal to the first direction, and the alignment direction thereof may be appropriately changed.

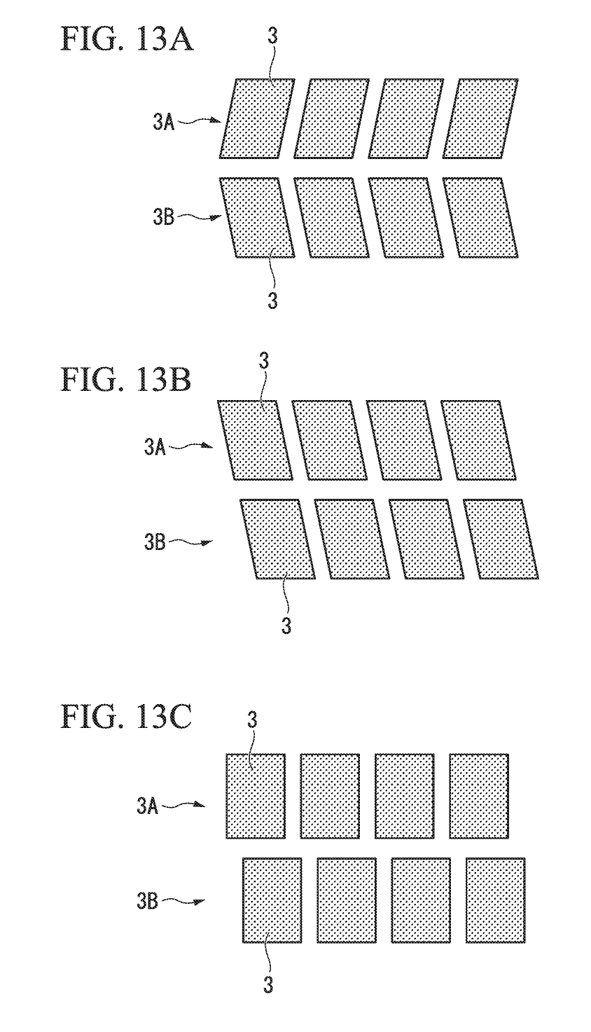

Specifically, plan views illustrating the arrangement of multiple thermoelectric conversion elements 3 constituting the pair of thermoelectric conversion element arrays 3A and 3B are shown in FIGS. 13A to 13C.

Among them, in the configuration illustrated in FIG. 13A, multiple thermoelectric conversion elements 3 constituting the one thermoelectric conversion element array 3A and multiple thermoelectric conversion elements 3 constituting the other thermoelectric conversion element array 3B have a parallelogram shape inclined in an opposite direction in a plan view in the first direction (a horizontal direction in FIG. 13), are arranged side by side in the first direction, and are arranged side by side in the second direction (a vertical direction in FIG. 13) which is orthogonal to the first direction.

On the other hand, in a configuration illustrated in FIG. 13B, multiple thermoelectric conversion elements 3 constituting one thermoelectric conversion element array 3A and multiple thermoelectric conversion elements 3 constituting the other thermoelectric conversion element array 3B have a parallelogram shape inclined in the same direction in a plan view in the first direction (a horizontal direction in FIG. 13), are arranged side by side in the first direction, and are arranged side by side in the second direction (a vertically oblique direction in FIG. 13) which is oblique with respect to the first direction.

On the other hand, in a configuration illustrated in FIG. 13C, multiple thermoelectric conversion elements 3 constituting one thermoelectric conversion element array 3A and multiple thermoelectric conversion elements 3 constituting the other thermoelectric conversion element array 3B have a rectangular shape in a plan view, are arranged side by side in the first direction, and are arranged with a shift side by side in the second direction (a vertically oblique direction in FIG. 13) which is oblique with respect to the first direction.

Further, although the thermoelectric conversion devices 1A and 1B in which a pair (two columns) of thermoelectric conversion element arrays 3A and 3B are arranged are illustrated in the above-described embodiments, the number of thermoelectric conversion element arrays 3A and 3B to be arranged can also be increased.

Further, in the thermoelectric conversion device 1B, the first wiring 10 which does not intersect with the second wiring 11 partially exists. However, the present invention is not limited to the configuration in which all of the wirings 10 and 11 intersect each other as in the thermoelectric conversion device 1A, and only some of the wirings 10 and 11 may intersect each other. Further, in the thermoelectric conversion device 1B, one second wiring 11 intersects two first wirings 10. However, the present invention is not limited to the configuration in which one wiring 10 intersects one wiring 11 as in the thermoelectric conversion device 1A, and a configuration in which one wiring 10 or 11 intersects multiple wirings 11 or 10 may be adopted.

Although the configuration in which multiple thermoelectric conversion elements 3 each formed of any one of the p-type semiconductor and the n-type semiconductor are arranged side by side on the surface of the substrate 2 has been illustrated in the above embodiment, a configuration in which a pair of thermoelectric conversion element arrays 3A and 3B each including multiple thermoelectric conversion elements 3 each formed of the p-type semiconductor, and a pair of thermoelectric conversion element arrays 3A and 3B including multiple thermoelectric conversion elements 3 each formed of the n-type semiconductor may be arranged side by side on the surface of the substrate 2 may be adopted.

Further, although the configuration in which one substrate 2 on which multiple thermoelectric conversion elements 3 are arranged is sandwiched between the first heat transfer plate 5 and the second heat transfer plate 6 has been illustrated in the above embodiment, a configuration in which multiple substrates 2 on which multiple thermoelectric conversion elements 3 are arranged are sandwiched between the first heat transfer plate 5 and the second heat transfer plate 6 may be adopted.

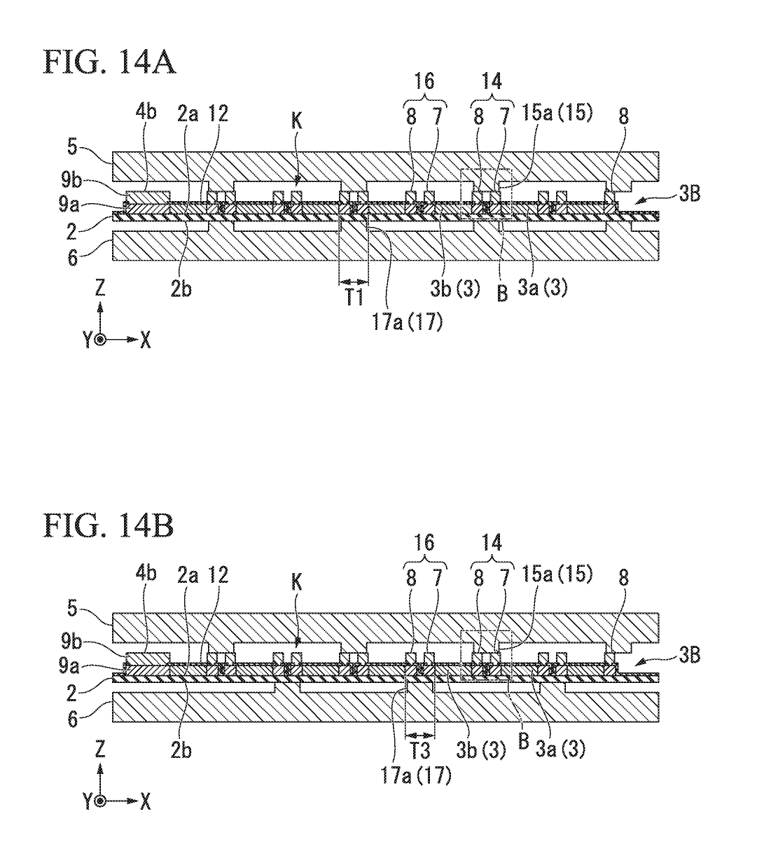

Although the second heat transfer plate 6 is thermally bonded to the entire surface of the second surface 2b of the substrate 2 has been illustrated in the above embodiment, a configuration, for example, as illustrated in FIGS. 14A and 14B may be adopted. FIGS. 14A and 14B illustrate a modification example of the second heat transfer plate 6 using a cross cross-sectional view corresponding to the cross-sectional view of the thermoelectric conversion device 1 taken along a line segment A-A illustrated in FIG. 1.

Specifically, in a configuration illustrated in FIG. 14A, the second heat transfer plate 6 is thermally bonded to the substrate 2 via the heat transfer portion 17 in the range T1 in which the second heat transfer plate 6 overlaps the heat transfer portion 15 (the protrusion 15a) in the thickness direction. The heat transfer portion 17 has a protrusion 17a protruding from the surface side of any one (the second heat transfer plate 6 in FIG. 14A) of the mutually facing surfaces of the second heat transfer plate 6 and the substrate 2, and the second heat transfer plate 6 and the substrate 2 are thermally bonded to each other.

On the other hand, in a configuration illustrated in FIG. 14B, the second heat transfer plate 6 is thermally bonded to the substrate 2 via the heat transfer portion 17 (the protrusion 17a) in the range T3 in which the second heat transfer plate 6 overlaps the cold junction side electrode 16 in the thickness direction.

In addition, although thermoelectric conversion devices 1A and 1B, in which the first heat transfer plate 5 is configured to be the high temperature side and the second heat transfer plate 6 is configured to be the low temperature side, are described as an example in the above-described embodiments, the first heat transfer plate 5 may be configured to be the low temperature side and the second heat transfer plate 6 may be configured to be the high temperature side.

Further, the second heat transfer plate 6 is not necessarily required and may be omitted in some cases.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A thermoelectric conversion device comprising:
a substrate including a first surface and a second surface facing each other in a thickness direction;
a pair of thermoelectric conversion element arrays including a plurality of thermoelectric conversion elements aligned in a first direction among the first direction and a second direction intersecting each other in a surface on the first surface side of the substrate, the plurality of thermoelectric conversion elements being arranged side by side in the second direction;
a first electrode electrically connected to one end in the first direction of each of the thermoelectric conversion elements constituting the thermoelectric conversion element array and a second electrode electrically connected to the other end in the first direction of each of the thermoelectric conversion elements; and
a first wiring and a second wiring that are arranged between one thermoelectric conversion element array and the other thermoelectric conversion element array adjacent to each other in the second direction, and electrically connect any two of a plurality of the first electrodes and a plurality of the second electrodes of each thermoelectric conversion element so that the thermoelectric conversion elements constituting the one thermoelectric conversion element array and the thermoelectric conversion elements constituting the other thermoelectric conversion element array are alternately connected in series,
wherein the first wiring and the second wiring are arranged so that the wirings at least partially intersect each other with an insulating layer therebetween as viewed in the thickness direction of the substrate.

2. The thermoelectric conversion device according to claim 1, wherein a first thermoelectric conversion element through which a current flows from the first electrode side to the second electrode side and a second thermoelectric conversion element through which a current flows from the second electrode side to the first electrode side among the thermoelectric conversion elements constituting the thermoelectric conversion element array are alternately arranged side by side in the first direction.

3. The thermoelectric conversion device according to claim 2, wherein the thermoelectric conversion elements in which directions of the currents flowing between the first electrode and the second electrode are opposite are arranged side by side in the second direction among the thermoelectric conversion elements constituting the pair of thermoelectric conversion element arrays.

4. The thermoelectric conversion device according to claim 2, wherein the thermoelectric conversion elements in which directions of the currents flowing between the first electrode and the second electrode are a same direction are arranged side by side in the second direction among the thermoelectric conversion elements constituting the pair of thermoelectric conversion element arrays.

5. The thermoelectric conversion device according to claim 1, wherein
the first electrode and the second electrode are made of a laminated film in which a first conductive film and a second conductive film are sequentially laminated,
the first wiring is made of any one of the first conductive film and the second conductive film, and
the second wiring is made of the other of the first conductive film and the second conductive film.

6. The thermoelectric conversion device according to claim 2, wherein
the first electrode and the second electrode are made of a laminated film in which a first conductive film and a second conductive film are sequentially laminated,
the first wiring is made of any one of the first conductive film and the second conductive film, and
the second wiring is made of the other of the first conductive film and the second conductive film.

7. The thermoelectric conversion device according to claim 3, wherein
the first electrode and the second electrode are made of a laminated film in which a first conductive film and a second conductive film are sequentially laminated,
the first wiring is made of any one of the first conductive film and the second conductive film, and
the second wiring is made of the other of the first conductive film and the second conductive film.

8. The thermoelectric conversion device according to claim 4, wherein
the first electrode and the second electrode are made of a laminated film in which a first conductive film and a second conductive film are sequentially laminated,
the first wiring is made of any one of the first conductive film and the second conductive film, and
the second wiring is made of the other of the first conductive film and the second conductive film.

9. The thermoelectric conversion device according to claim 1, further comprising a first heat transfer part arranged on the first surface side of the substrate,
wherein an electrode configured to be a hot junction side among the first electrode and the second electrode is thermally bonded to the first heat transfer part.

10. The thermoelectric conversion device according to claim 2, further comprising a first heat transfer part arranged on the first surface side of the substrate,
wherein an electrode configured to be a hot junction side among the first electrode and the second electrode is thermally bonded to the first heat transfer part.

11. The thermoelectric conversion device according to claim 3, further comprising a first heat transfer part arranged on the first surface side of the substrate,
wherein an electrode configured to be a hot junction side among the first electrode and the second electrode is thermally bonded to the first heat transfer part.

12. The thermoelectric conversion device according to claim 4, further comprising a first heat transfer part arranged on the first surface side of the substrate,
wherein an electrode configured to be a hot junction side among the first electrode and the second electrode is thermally bonded to the first heat transfer part.

13. The thermoelectric conversion device according to claim 5, further comprising a first heat transfer part arranged on the first surface side of the substrate,
wherein an electrode configured to be a hot junction side among the first electrode and the second electrode is thermally bonded to the first heat transfer part.

14. The thermoelectric conversion device according to claim 6, further comprising a first heat transfer part arranged on the first surface side of the substrate,
wherein an electrode configured to be a hot junction side among the first electrode and the second electrode is thermally bonded to the first heat transfer part.

15. The thermoelectric conversion device according to claim 7, further comprising a first heat transfer part arranged on the first surface side of the substrate,
wherein an electrode configured to be a hot junction side among the first electrode and the second electrode is thermally bonded to the first heat transfer part.

16. The thermoelectric conversion device according to claim 8, further comprising a first heat transfer part arranged on the first surface side of the substrate,
wherein an electrode configured to be a hot junction side among the first electrode and the second electrode is thermally bonded to the first heat transfer part.

17. The thermoelectric conversion device according to claim 9, further comprising a second heat transfer part arranged on the second surface side of the substrate and thermally bonded to the substrate.

18. The thermoelectric conversion device according to claim 10, further comprising a second heat transfer part arranged on the second surface side of the substrate and thermally bonded to the substrate.

19. The thermoelectric conversion device according to claim 11, further comprising a second heat transfer part arranged on the second surface side of the substrate and thermally bonded to the substrate.

20. The thermoelectric conversion device according to claim 12, further comprising a second heat transfer part arranged on the second surface side of the substrate and thermally bonded to the substrate.
